(19) United States
(12) Patent Application Publication
(10) Pub. No.: US 2024/0331999 A1
(43) Pub. Date: Oct. 3, 2024

(54) SYSTEMS AND METHODS FOR NANOHOLE WET CLEANS

(71) Applicant: Applied Materials, Inc., Santa Clara, CA (US)

(72) Inventors: Ying-Bing Jiang, Woodland, CA (US); Avgerinos V. Gelatos, Scotts Valley, CA (US); Joung Joo Lee, San Jose, CA (US); Bencherki Mebarki, Santa Clara, CA (US); Xianmin Tang, San Jose, CA (US); In Seok Hwang, Pleasanton, CA (US); Zhijun Chen, San Jose, CA (US)

(73) Assignee: Applied Materials, Inc., Santa Clara, CA (US)

(21) Appl. No.: 18/442,681

(22) Filed: Feb. 15, 2024

Related U.S. Application Data
(60) Provisional application No. 63/456,256, filed on Mar. 31, 2023.

(51) Int. Cl. H01L 21/02; H01L 21/311

(52) U.S. Cl. CPC H01L 21/0206; H01L 21/31111

(57) ABSTRACT

Exemplary semiconductor processing methods may include providing a substrate to a processing region of a semiconductor processing chamber. The substrate may include an alternating stack of materials. A feature may extend through the alternating stack of materials. One material of the alternating stack of materials may include a silicon-containing material. A native oxide material may be disposed on at least a portion of exposed surfaces of the silicon-containing material. The methods may include performing a pre-clean treatment on the substrate. The methods may include providing a fluorine-containing precursor to the processing region. The methods may include contacting the substrate with the fluorine-containing precursor, wherein the contacting removes native oxide from the silicon-containing material.

### CROSS-REFERENCE TO RELATED APPLICATIONS

This application claims the benefit of, and priority to U.S. Provisional Application Ser. No. 63/456,256, filed Mar. 31, 2023, which is hereby incorporated by reference in its entirety for all purposes.

### TECHNICAL FIELD

The present technology relates to semiconductor processes and products. More specifically, the present technology relates to selectively etching material layers on a substrate.

### BACKGROUND

Integrated circuits are made possible by processes which produce intricately patterned material layers on substrate surfaces. Producing patterned material on a substrate requires controlled methods for deposition and removal of exposed material. Chemical etching is used for a variety of purposes including transferring a pattern in photoresist into underlying layers, thinning layers, or removing native oxides present on the surface. Often it is desirable to have an etch process that etches one material faster than another facilitating, for example, a pattern transfer process or individual material removal. Such an etch process is said to be selective to the first material. As a result of the diversity of materials, circuits, and processes, etch processes have been developed with a selectivity towards a variety of materials.

Etch processes may be termed wet or dry based on the materials used in the process. For example, a wet etch may preferentially remove some oxide dielectrics over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a substrate to a processing region of a semiconductor processing chamber. The substrate may include an alternating stack of materials. A feature may extend through the alternating stack of materials. One material of the alternating stack of materials may include a silicon-containing material. A native oxide material may be disposed on at least a portion of exposed surfaces of the silicon-containing material. The methods may include performing a pre-clean treatment on the substrate. The methods may include providing a fluorine-containing precursor to the processing region. The methods may include contacting the substrate with the fluorine-containing precursor, wherein the contacting removes native oxide from the silicon-containing material.

In embodiments, the alternating stack of materials may include a first nitrogen-containing material. The silicon-containing material may overly the first nitrogen-containing material. A second nitrogen-containing material may overly the silicon-containing material. An oxygen-containing material may overly the second nitrogen-containing material. The feature may be characterized by an aspect ratio of greater than or about 10:1. The pre-clean treatment may include introducing water or steam to the substrate and filling the feature extending through the alternating stack of materials. The pre-clean treatment may include agitating the substrate to remove an air bubble from the feature. The pre-clean treatment condensing the steam at a lower portion of the feature extending through the alternating stack of materials. The feature may be filled from a bottom of the feature to a top of the feature. The feature may be filled without formation of an air bubble. The methods may include providing a surfactant to the processing region during the pre-clean treatment, with the fluorine-containing precursor, or both. The surfactant may be or include a hydrophilic hydrocarbon. The fluorine-containing precursor may be or include dilute hydrofluoric acid.

Some embodiments of the present technology encompass semiconductor processing methods. The methods may include providing a substrate to a processing region of a semiconductor processing chamber. The substrate may include an alternating stack of materials. A feature may extend through the alternating stack of materials. One material of the alternating stack of materials may include a silicon-containing material. A native oxide material may be disposed on at least a portion of exposed surfaces of the silicon-containing material. The methods may include providing a fluorine-containing precursor to the processing region. The methods may include contacting the substrate with the fluorine-containing precursor. The contacting may remove native oxide from the silicon-containing material. The contacting may not form a bubble at a lower portion of the feature.

In embodiments, the alternating stack of materials may include a first nitrogen-containing material. The silicon-containing material may overly the first nitrogen-containing material. A second nitrogen-containing material may overly the silicon-containing material. An oxygen-containing material may overly the second nitrogen-containing material. A height of the feature may be greater than or about 2 μm. A pressure in the processing region may be less than or about 1,000 Torr. The methods may include providing a surfactant to the processing region with the fluorine-containing precursor. The surfactant may be or include a hydrophilic hydrocarbon. The methods may include performing a pre-clean treatment on the substrate. The pre-clean treatment may include filling the feature with water from a bottom of the feature to a top of the feature. Prior to performing the pre-clean treatment on the substrate or contacting the substrate with the fluorine-containing precursor, the methods may include cooling the substrate. A relative humidity in the processing region may be maintained at greater than or about 70%.

Some embodiments of the present technology encompass semiconductor processing systems. The systems may include a semiconductor processing chamber defining a processing region. The systems may include a water vaporizer in fluid communication with the processing region. The water vaporizer may be operable to adjust a relative humidity in the processing region. The systems may include a cooling unit in fluid communication with the processing region. The cooling unit may be operable to deliver cooling fluid to the processing region. The systems may include an acid container in fluid communication with the processing region. The acid container may be operable to deliver an etchant species to the processing region.

Such technology may provide numerous benefits over conventional semiconductor processing methods and structures. For example, embodiments of the processing methods may reduce or eliminate the presence air bubbles in high aspect ratio features during native oxide cleaning operations. By reducing or eliminating the presence of air bubbles in high aspect ratio features during cleaning operations, uniform native oxide removal may be achieved while minimizing removal of other materials. Additionally, removal time of native oxide may be reduced as air bubbles may already be removed from the features. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows a schematic diagram of an exemplary semiconductor processing system according to some embodiments of the present technology.

FIG. 3 shows a block diagram illustrating an exemplary computer system upon which embodiments of the present invention may be implemented according to some embodiments of the present technology.

FIG. 4 shows exemplary operations in a method according to some embodiments of the present technology.

FIGS. 5A-5C show cross-sectional views of a substrate being processed according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Diluted acids may be used in many different semiconductor processes for cleaning substrates and removing materials from those substrates. For example, diluted hydrofluoric acid can be an effective etchant for silicon oxide, titanium oxide, and other materials, and may be used to remove these materials from substrate surfaces. After the etching or cleaning operation is complete, the acid may be dried from the wafer or substrate surface. Using dilute hydrofluoric acid (“DHF”) may be termed a “wet” etch, and the diluent is often water. Additional etching processes may be used that utilize precursors delivered to the substrate. For example, plasma enhanced processes may also selectively etch materials by enhancing precursors through the plasma to perform a dry etch, including a reactive ion etching.

Although wet etchants using aqueous solutions or water-based processes may operate effectively for certain substrate structures, reduced feature sizes and increased aspect ratios may frustrate wet etch operations, such as native oxide removal operations from silicon-containing material. For example, air bubbles may become trapped at lower portions of features, such as holes or trenches, patterned into a stack of material. If trapped air bubbles are not forced out, the cleaning or etching may not be uniform. In order to remove trapped air bubbles, agitation may be needed to force the air bubbles out of the features, which may increase overall contact time between the substrate and acid. With increased contact time, overetching may occur at upper portions of the features, which may result in damaged structures.

Embodiments of the present technology address the problems with conventional wet etch processes by performing a pre-clean treatment or utilizing a surfactant. The pre-clean treatment may include soaking the substrate in water, with optional agitation, to fill the feature completely with water. Alternatively, the pre-clean treatment may include condensing water in the feature through capillary condensation to fill the feature from the bottom up. A surfactant with higher vapor pressure than water or the acid used during the cleaning or etching may also be provided during the pre-clean treatment or with the acid. The high vapor pressure of the surfactant may force air bubbles out of the feature. By performing a pre-clean treatment or utilizing a surfactant, contact time between the substrate and acid may be reduced while increasing uniformity of native oxide removal within the feature.

Although the remaining disclosure will routinely identify specific etching processes utilizing the disclosed technology, it will be readily understood that the systems and methods are equally applicable to deposition and cleaning processes as may occur in the described chambers, as well as other etching technology including mid and back-end-of-line processing and other etching that may be performed with a variety of exposed materials that may be maintained or substantially maintained. Accordingly, the technology should not be considered to be so limited as for use with the exemplary etching processes or chambers alone. Moreover, although an exemplary chamber is described to provide foundation for the present technology, it is to be understood that the present technology can be applied to virtually any semiconductor processing chamber that may allow the operations described.

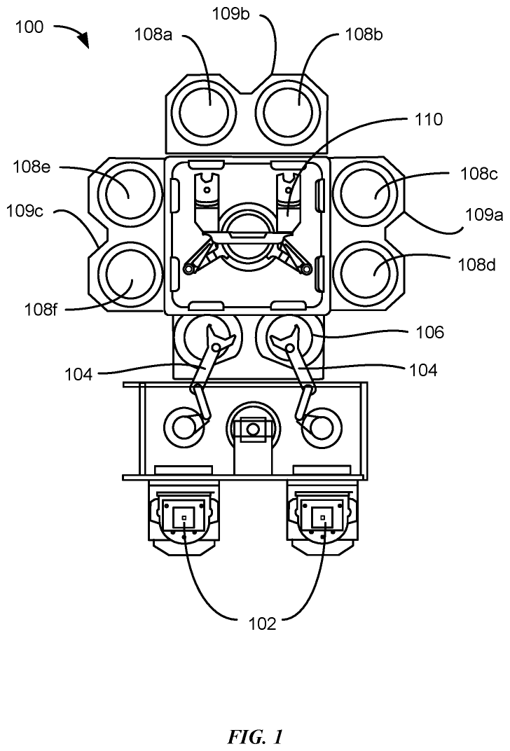

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

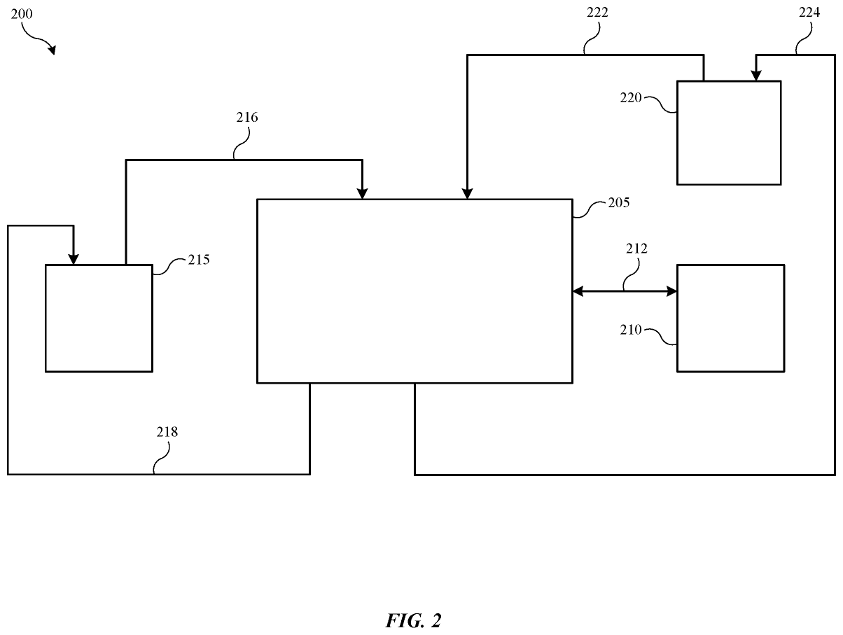

FIG. 2 shows a schematic diagram of a semiconductor processing system 200. The system 200 may be included as part of processing system 100. System 200 may include a semiconductor processing chamber 205. Semiconductor processing chamber 205 may be, for example, one substrate processing chambers 108a-f of processing system 100. Semiconductor processing chamber 205 may define a processing region, which may house a substrate during processing.

A water vaporizer 210 may be in fluid communication with the processing region of the semiconductor processing chamber 205. The water vaporizer 210 may be in fluid communication with the processing region of the semiconductor processing chamber 205 via supply line 212. The water vaporizer 210 may adjust a relative humidity in the processing region of the semiconductor processing chamber 205. For example, during processing, relative humidity may be adjusted in the processing region. The water vaporizer 210 may increase the relative humidity to, for example, greater than or about 10% or more, as further discussed below.

A cooling unit 215 may be in fluid communication with the processing region of the semiconductor processing chamber 205. The cooling unit 215 may deliver cooling fluid to the processing region of the semiconductor processing chamber 205. The cooling unit 215 may be, for example, a water bath, a water vaporizer, or a cooling air blower. For example, the water vaporizer may be an ultrasonic water vaporizer. The cooling unit 215 may be in fluid communication with the processing region of the semiconductor processing chamber 205 via supply line 216. Return line 218 may fluidly couple the processing region of the semiconductor processing chamber 205 and the cooling unit 215 to return cooling fluid to the cooling unit 215.

An acid container 220 may be in fluid communication with the processing region of the semiconductor processing chamber 205. The acid container 220 may deliver an etchant species to the processing region of the semiconductor processing chamber 205. The acid container 220 may be in fluid communication with the processing region of the semiconductor processing chamber 205 via supply line 222. Return line 224 may fluidly couple the processing region of the semiconductor processing chamber 205 and the acid container 220 to return etchant species to the acid container 220. While not depicted, a filtration device may be present along the return line 224 to remove byproducts from the etchant species.

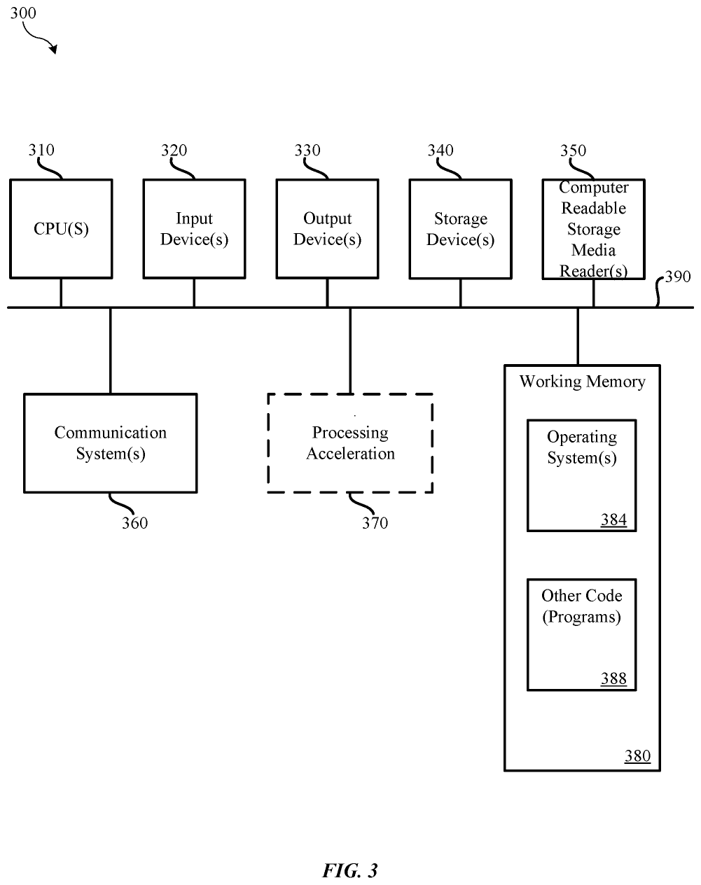

FIG. 3 is a block diagram illustrating an exemplary computer system upon which embodiments of the present invention may be implemented. This example illustrates a computer system 300 such as may be used, in whole, in part, or with various modifications, to provide the functions of the system 10, as well as other components and functions of the invention described herein.

The computer system 300 is shown comprising hardware elements that may be electrically coupled via a bus 390. The hardware elements may include one or more central processing units 310, one or more input devices 320 (e.g., a mouse, a keyboard, etc.), and one or more output devices 330 (e.g., a display device, a printer, etc.). The computer system 300 may also include one or more storage devices 340, representing remote, local, fixed, and/or removable storage devices and storage media for temporarily and/or more permanently containing computer-readable information, and one or more storage media reader(s) 350 for accessing the storage device(s) 340. By way of example, storage device(s) 340 may be disk drives, optical storage devices, solid-state storage device such as a random access memory (“RAM”) and/or a read-only memory (“ROM”), which can be programmable, flash-updateable or the like.

The computer system 300 may additionally include a communications system 360 (e.g., a modem, a network card-wireless or wired, an infra-red communication device, a Bluetooth™ device, a near field communications (NFC) device, a cellular communication device, etc.) The communications system 360 may permit data to be exchanged with a network, system, computer, mobile device and/or other component as described earlier. The system 300 also includes working memory 380, which may include RAM and ROM devices as described above. In some embodiments, the computer system 300 may also include a processing acceleration unit 370, which can include a digital signal processor, a special-purpose processor and/or the like.

The computer system 300 may also comprise software elements, shown as being located within a working memory 380, including an operating system 384 and/or other code 388.

Software code 388 may be used for implementing functions of various elements of the architecture as described herein. For example, software stored on and/or executed by a computer system, such as system 300, can be used in implementing the processes described herein.

It should be appreciated that alternative embodiments of a computer system 300 may have numerous variations from that described above. For example, customized hardware might also be used and/or particular elements might be implemented in hardware, software (including portable software, such as applets), or both. Furthermore, there may be connection to other computing devices such as network input/output and data acquisition devices (not shown).

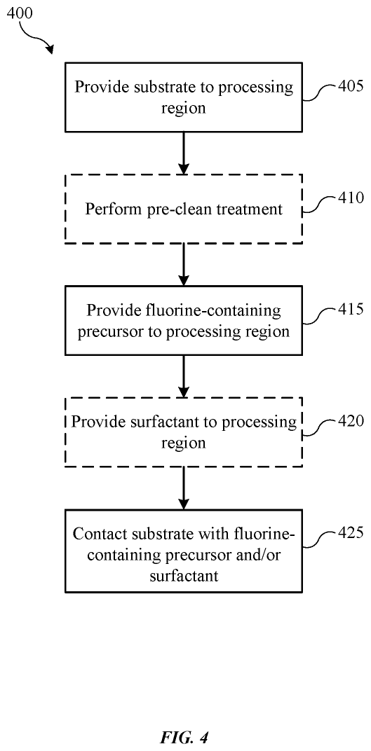

System 100, or more specifically chambers incorporated into system 100, including chamber 200, or other processing systems, may be used to produce semiconductor structures according to some embodiments of the present technology. FIG. 4 illustrates a method 400 of forming a semiconductor structure, many operations of which may be performed, for example, in the chamber 200 as previously described. Method 400 may include one or more operations prior to the initiation of the method, including front end processing, polishing, cleaning, deposition, etching, or any other operations that may be performed prior to the described operations. The method may include a number of optional operations as denoted in the figure, which may or may not be specifically associated with the method according to the present technology. For example, many of the operations are described in order to provide a broader scope of the structural formation, but are not critical to the technology, or may be performed by alternative methodology as will be discussed further below.

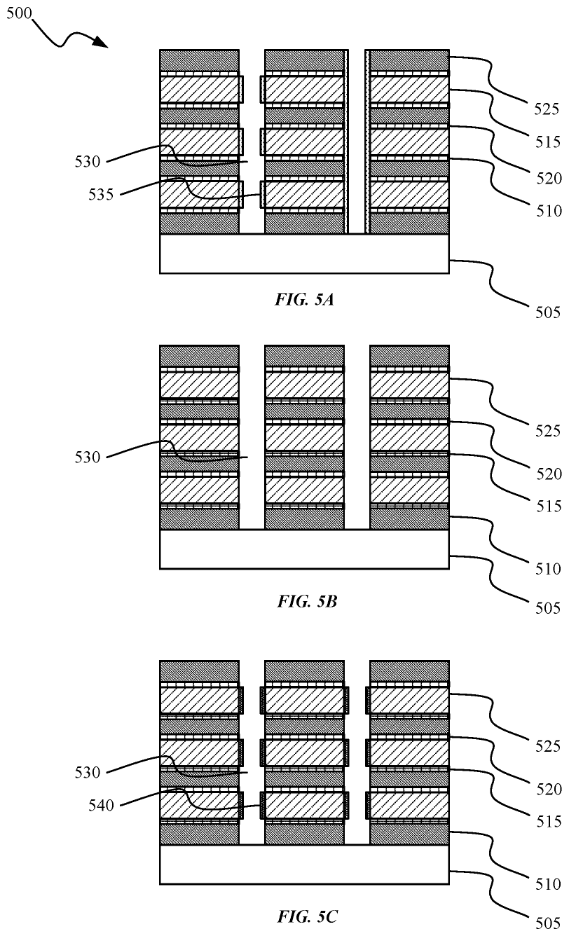

Method 400 describes the operations shown schematically in FIGS. 5A-5C, the illustrations of which will be described in conjunction with the operations of method 400. It is to be understood that FIGS. 5A-5C illustrate only partial schematic views, and a structure 500 or a substrate 505 may contain any number of transistor sections having aspects as illustrated in the figures. The operations of method 400 may be performed to increase a uniformity in native oxide removal in a feature extending through an alternating stack of materials on the substrate 505. The operations of method 300 may also be performed to prevent over etching of one or more materials in the alternating stack of materials on the substrate 505. The operations of method 400 may also be performed to decrease queue times during native oxide removal in the feature extending through the alternating stack of materials on the substrate 505.

The method 400 may begin at operation 405 by the substrate 505 to a processing region of a semiconductor processing chamber, such as the processing region of chamber 205. The substrate 505 may be made of or contain silicon or some other semiconductor substrate material. As previously discussed, and as shown in FIG. 5A, the substrate 505 may include an alternating stack of materials. For example, the materials may include one or more silicon-containing materials, one or more silicon-and-nitrogen-containing materials, and one or more silicon-and-oxygen-containing materials. In the exemplary embodiment shown in FIG. 5A, the alternating stack of materials may include a first nitrogen-containing material 510, such as a silicon-and-nitrogen-containing material. A silicon-containing material 515, such as polysilicon, may overly the first nitrogen-containing material 510. A second nitrogen-containing material 520, such as a silicon-and-nitrogen-containing material, may overly the silicon-containing material. In embodiments, the first nitrogen-containing material 510 and the second nitrogen-containing material 520 may be the same material. An oxygen-containing material 525, such as a silicon-and-oxygen-containing material, may overly the second nitrogen-containing material. The next alternating stack of materials may include another layer of the first nitrogen-containing material 510 overlying the oxygen-containing material 525.

While the structure 500 shown in FIGS. 5A-5C depict only 3 portions of an alternating stack of materials, it is contemplated that a substrate 505 may have any number of materials deposited thereon. For example, the substrate 505 may include greater than 5 portions of an alternating stack of materials, such as greater than 7, greater than 10, greater than 15, greater than 20, greater than 25, greater than 30, greater than 35, greater than 40, greater than 45, greater than 50, greater than 55, greater than 60, greater than 65, greater than 70, greater than 75, or more portions of an alternating stack of materials.

A feature 530, such as a trench or hole, may extend through the alternating stack of materials. An aspect ratio or the height-to-width ratio of the feature 530 may be greater than or about 10:1, greater than or about 15:1, greater than or about 20:1, greater than or about 25:1, greater than or about 30:1, greater than or about 35:1, greater than or about 40:1, or greater. A height or depth of the feature 530 may be greater than or about 1 μm, such as greater than or about 1.2 μm, greater than or about 1.4 μm, greater than or about 1.6 μm, greater than or about 1.8 μm, greater than or about 2 μm, such as greater than or about 2.2 μm, greater than or about 2.4 μm, greater than or about 2.6 μm, greater than or about 2.8 μm, greater than or about 3 μm, or more. Additionally, each layer may be characterized by a reduced width or thickness less than or about 100 nm, such as less than or about 80 nm, less than or about 60 nm, less than or about 50 nm, less than or about 40 nm, less than or about 30 nm, less than or about 20 nm, less than or about 10 nm, less than or about 5 nm, less than or about 1 nm, or less, including any fraction of any of the stated numbers, such as 20.5 nm, 1.5 nm, etc. As further discussed below, this combination of high aspect ratios and minimal thicknesses may frustrate many conventional etching operations, or require substantially longer etch times to remove a layer, along a vertical or horizontal distance through a confined width. Moreover, damage to or removal of other exposed layers may occur with conventional technologies as well.

A native oxide material 535 may be present along at least a portion of exposed surfaces of the feature, such as along the silicon-containing material. The native oxide material 535 may form due to exposure to ambient conditions after etching of the features 530 through the alternating stack of materials. As shown in the left feature in FIG. 5A, the native oxide material 535 may form only on the exposed surfaces of the silicon-containing material 515. However, as shown in the right feature 530 in FIG. 5A, the native oxide material 535 may form on all exposed surfaces of the alternating stack of materials. Any amount of coverage of native oxide material 535 on exposed surfaces within the feature 530 is contemplated.

It is to be understood that the noted structure 500 is not intended to be limiting, and any of a variety of other semiconductor structures are similarly encompassed. Other exemplary structures may include two-dimensional and three-dimensional structures common in semiconductor manufacturing, and within or on which a native oxide is to be removed relative to one or more other materials, as the present technology may selectively remove native oxide relative to any number of other materials, including each material noted above. Additionally, although a high-aspect-ratio structure may benefit from the present technology, the technology may be equally applicable to lower aspect ratios and any other structures.

At optional operation 410, method 400 may include performing a pre-clean treatment on the substrate 505. In conventional processes to remove native oxide material from within the features extending through alternating stacks of materials on substrates, etchant species may be provided to the substrate without performing a pre-clean treatment. However, as aspect ratios of features extending through alternating stack of materials on substrates continue to increase, the etchant species may not immediately reach the bottom of the feature. Instead, one or more air bubbles may form and become trapped at the bottom of the features. The presence of the air bubbles may prevent the etchant species from immediately reaching the bottom of the feature. Accordingly, native oxide material may not be removed from lower portions of the feature. In order to perform a complete removal of the native oxide, the etchant species may need to remain within the feature for increased periods of time. However, due to the increased contact time of the etchant species within the feature, the etchant species may begin etching one or more materials of the alternating stack of materials. The etching of one or more materials of the alternating stack of materials may damage the structure.

Accordingly, performing the pre-clean treatment may reduce or prevent the formation and/or trapping of air bubbles at the bottom of the features 530. In one embodiment, the pre-clean treatment may include introducing water or steam to the processing region and/or the substrate 505. In order to reduce or prevent formation and/or trapping of air bubble, the pre-clean treatment may include filling the feature 530 extending through the alternating stack of materials. In embodiments, the pre-clean treatment may continue for a sufficient period of time to allow the water or steam to fill the feature 530. However, it is also contemplated that the pre-clean treatment may continue for a period of time to fill at least 25 vol. %, at least 30 vol. %, at least 35 vol. %, at least 40 vol. %, at least 45 vol. %, at least 50 vol. %, at least 65 vol. %, at least 60 vol. %, at least 65 vol. %, at least 70 vol. %, at least 75 vol. %, at least 80 vol. %, at least 85 vol. %, at least 90 vol. %, at least 95 vol. %, at least 97 vol. %, at least 99 vol. %, or more of the feature 530 extending through the alternating stack of materials on the substrate 505. By partially filling the feature 530, the aspect ratio of the feature 530 that remains unfilled may be effectively reduced to prevent formation and/or trapping of air bubbles.

In embodiments, the pre-clean treatment may include agitating the substrate 505. By agitating the substrate 505, the feature 530 extending through the alternating stack of materials may be filled in a shorter period of time. Additionally, agitation may ensure all features 530 across a substrate are filled. To agitate the substrate 505, the substrate 505 may be vibrated or ultrasonic sounds waves may be directed at the substrate 505. Alternatively, the substrate 505 may be agitated by a water jet or through vacuum soaking. It is contemplated that any means of agitation may be used to expedite filling of the feature 530 with reduced or eliminated formation and/or trapping of air bubbles at the bottom of the features 530. The pre-clean treatment may include soaking the substrate 505 in water, such as deionized water. By soaking the substrate 505 in water, such as for an extended period of time, along with optional agitation, the features 530 may be fully filled without the presence of any air bubbles.

In embodiments, a reduced substrate temperature may facilitate filling the features 530. Accordingly, method 400 may include reducing substrate temperature prior to or during the pre-clean treatment. In embodiments, the substrate temperature may be reduced prior to or during the pre-clean treatment to less than or about 300° C., such as less than or about 280° C., less than or about 260° C., less than or about 240° C., less than or about 220° C., less than or about 200° C., less than or about 180° C., less than or about 160° C., less than or about 140° C., less than or about 120° C., less than or about 100° C., or less. By reducing substrate temperature, vapor may preferentially condense at the lower portion of the feature 530 due to capillary condensation. As capillary condensation may start at the lower portion of the feature 530 and gradually fill the feature 530 from bottom to top, air bubble formation and/or trapping will be reduced or eliminated.

Similarly, efficient filling of the feature 530 extending through the alternating stack of materials during the pre-clean treatment may increase under high humidity. For example, with high humidity, lower portions of the feature 530 may become saturated, causing steam to condense and fill the feature 530 from the bottom first. In embodiments, the relative humidity may be greater than or about 60%, greater than or about 65%, greater than or about 70%, greater than or about 75%, greater than or about 80%, greater than or about 85%, greater than or about 90%, or greater than or about 95%, greater than or about 99%, or higher. Similar to reduced temperature, with increased humidity, vapor may preferentially condense at the lower portion of the feature 530 and gradually fill the feature 530 from bottom to top without forming and/or trapping air bubbles.

Method 400 may include providing a fluorine-containing precursor to the processing region at operation 415. An exemplary fluorine-containing precursor used in method 400 may include hydrofluoric acid or ammonium fluoride. However, various other fluorine-containing precursors used or useful in semiconductor processing are also contemplated. Other sources of fluorine may be used in conjunction with or as replacements for the hydrofluoric acid. In embodiments, the fluorine-containing precursor may be in solution with water to dilute the fluorine-containing precursor.

In embodiments, a surfactant may be provided with the fluorine-containing precursor at optional operation 420. In the event an air bubble forms or becomes trapped within the feature 530, the surfactant may serve to destabilize the air bubble and force the air bubble out of the feature 530. The surfactant may be characterized by high vapor pressure, which may force the air bubble towards an upper portion of the feature 530 and eventually out of the feature 530. In embodiments, the surfactant may be characterized by a vapor pressure at room temperature of greater than or about 5 kPa, greater than or about 6 kPa, greater than or about 7 kPa, greater than or about 8 kPa, greater than or about 9 kPa, greater than or about 10 kPa, or higher. Exemplary surfactants may be hydrophilic hydrocarbons, such as ethanol, acetone, or isopropyl alcohol.

The surfactant may be provided with or without the performing the optional pre-clean treatment. It is also contemplated that the surfactant may be provided during the pre-clean treatment. In embodiments where the pre-clean treatment is not performed, the surfactant may still reduce or prevent formation and/or trapping of an air bubble in the feature 530. In embodiments where the pre-clean treatment is performed, the surfactant may reduce queue time by increasing the rate at which any formed air bubbles are removed.

After providing the fluorine-containing precursor and, optionally, the surfactant, method 400 may include contacting the substrate 505 with the fluorine-containing precursor and, if present, the surfactant at operation 425. The fluorine-containing precursor may remove the native oxide material 535 from within the feature 530. The native oxide material 530 may react with the fluorine-containing precursor to form byproducts such as hexafluorosilicic acid and water.

The pressure within the processing region may also affect the operations performed. In some embodiments the pressure may be maintained below about 1,000 Torr, below or about 950 Torr, below or about 900 Torr, below or about 850 Torr, below or about 800 Torr, below or about 790 Torr, below or about 780 Torr, below or about 770 Torr, below or about 760 Torr, below or about 750 Torr, or less. The pressure may also be maintained at any pressure within these ranges, within smaller ranges encompassed by these ranges, or between any of these ranges. In some embodiments the processing pressure may be maintained between about 750 Torr and about 1000 Torr, which may facilitate an initiation of the etch and may facilitate etching of the native oxide material 535.

In embodiments, performing the pre-clean treatment and/or providing the surfactant may reduce the overall time needed to remove the native oxide material 535 compared to conventional technologies. In conventional technologies where a pre-clean treatment is not performed and/or the surfactant is not provided, native oxide material removal for similar structures may require greater than five minutes of residence time. Even then, the presence of air bubbles may prevent native oxide from being removed from lower portions of the features and may overetch materials at upper portions of the features. Conversely, the present technology may uniformly remove native oxide material 535 throughout the features 530 in less than or about five minutes, less than or about four minutes, less than or about three minutes, less than or about two minutes, less than or about one minute, or less.

As shown in FIG. 5C, subsequent to removing the native oxide material 535 from the silicon-containing material 515, a metal silicide 540 may be selectively formed on the exposed silicon-containing material 515. For example, a molybdenum-and-silicon-containing material may be selectively formed on the exposed silicon-containing material 515. By performing operations of the present technology and removing native oxide material 535 from the silicon-containing material 515, the metal silicide 540 may form on all exposed layers of silicon-containing material 515 extending through the feature 530.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. “About” and/or “approximately” as used herein and in the appended claims when referring to a measurable value such as an amount, a temporal duration, and the like, encompasses variations of ±20%, ±10%, ±5%, or +0.1% from the specified value, as such variations are appropriate to in the context of the systems, devices, circuits, methods, and other implementations described herein. “Substantially” as used herein and in the appended claims when referring to a measurable value such as an amount, a temporal duration, a physical attribute (such as frequency), and the like, also encompasses variations of ±20%, ±10%, ±5%, or ±0.1% from the specified value, as such variations are appropriate to in the context of the systems, devices, circuits, methods, and other implementations described herein.

As used herein and in the appended claims, the singular forms “a”, “an”, and “the” include plural references unless the context clearly dictates otherwise. Thus, for example, reference to “a feature” includes a plurality of such features, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a substrate to a processing region of a semiconductor processing chamber, wherein the substrate comprises an alternating stack of materials, wherein a feature extends through the alternating stack of materials, wherein one material of the alternating stack of materials comprises a silicon-containing material, and wherein a native oxide material is disposed on at least a portion of exposed surfaces of the silicon-containing material;
performing a pre-clean treatment on the substrate;
providing a fluorine-containing precursor to the processing region; and
contacting the substrate with the fluorine-containing precursor, wherein the contacting removes native oxide from the silicon-containing material.

2. The semiconductor processing method of claim 1, wherein the alternating stack of materials comprises a first nitrogen-containing material, the silicon-containing material overlying the first nitrogen-containing material, a second nitrogen-containing material overlying the silicon-containing material, and an oxygen-containing material overlying the second nitrogen-containing material.

3. The semiconductor processing method of claim 1, wherein the feature is characterized by an aspect ratio of greater than or about 10:1.

4. The semiconductor processing method of claim 1, wherein the pre-clean treatment comprises:
introducing water or steam to the substrate; and
filling the feature extending through the alternating stack of materials.

5. The semiconductor processing method of claim 4, further comprising:
agitating the substrate to remove an air bubble from the feature.

6. The semiconductor processing method of claim 4, further comprising:
condensing the steam at a lower portion of the feature extending through the alternating stack of materials, wherein the feature is filled from a bottom of the feature to a top of the feature.

7. The semiconductor processing method of claim 6, wherein the feature is filled without formation of an air bubble.

8. The semiconductor processing method of claim 1, further comprising:
providing a surfactant to the processing region during the pre-clean treatment, with the fluorine-containing precursor, or both.

9. The semiconductor processing method of claim 8, wherein the surfactant comprises a hydrophilic hydrocarbon.

10. The semiconductor processing method of claim 1, wherein the fluorine-containing precursor comprises dilute hydrofluoric acid.

11. A semiconductor processing method comprising:
providing a substrate to a processing region of a semiconductor processing chamber, wherein the substrate comprises an alternating stack of materials, wherein a feature extends through the alternating stack of materials, wherein one material of the alternating stack of materials comprises a silicon-containing material, and wherein a native oxide material is disposed on at least a portion of exposed surfaces of the silicon-containing material;
providing a fluorine-containing precursor to the processing region; and
contacting the substrate with the fluorine-containing precursor, wherein the contacting removes native oxide from the silicon-containing material, and wherein the contacting does not form a bubble at a lower portion of the feature.

12. The semiconductor processing method of claim 11, wherein the alternating stack of materials comprises a first nitrogen-containing material, the silicon-containing material overlying the first nitrogen-containing material, a second nitrogen-containing material overlying the silicon-containing material, and an oxygen-containing material overlying the second nitrogen-containing material.

13. The semiconductor processing method of claim 11, wherein a height of the feature is greater than or about 2 μm.

14. The semiconductor processing method of claim 11, wherein a pressure in the processing region is less than or about 1,000 Torr.

15. The semiconductor processing method of claim 11, further comprising:
providing a surfactant to the processing region with the fluorine-containing precursor, wherein the surfactant comprises a hydrophilic hydrocarbon.

16. The semiconductor processing method of claim 11, further comprising:
performing a pre-clean treatment on the substrate.

17. The semiconductor processing method of claim 16, wherein the pre-clean treatment comprises filling the feature with water from a bottom of the feature to a top of the feature.

18. The semiconductor processing method of claim 16, further comprising:
prior to performing the pre-clean treatment on the substrate or contacting the substrate with the fluorine-containing precursor, cooling the substrate.

19. The semiconductor processing method of claim 16, wherein a relative humidity in the processing region is maintained at greater than or about 70%.

20. A semiconductor processing system comprising:
a semiconductor processing chamber defining a processing region;
a water vaporizer in fluid communication with the processing region, wherein the water vaporizer is operable to adjust a relative humidity in the processing region;
a cooling unit in fluid communication with the processing region, wherein the cooling unit is operable to deliver cooling fluid to the processing region; and
an acid container in fluid communication with the processing region, wherein the acid container is operable to deliver an etchant species to the processing region.
